(19) United States
(12) Patent Application Publication
(10) Pub. No.: US 2007/0188160 A1
(43) Pub. Date: Aug. 16, 2007

(54) Detection seat for IC detection device

(76) Inventor: Simon Shiu, Kaohsiung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/354,037

(22) Filed: Feb. 15, 2006

(51) Int. Cl. G01R 31/28

(52) U.S. Cl. 324/158.1

(57) ABSTRACT

A detection seat for an IC detection device includes a frame and an integrated circuit coupling seat. The frame is mounted on a detection board of an integrated circuit detection device. The IC coupling seat includes an outer perimeter releasably engaged with the frame. The IC coupling seat includes a recessed portion adapted for receiving an integrated circuit to be tested. The recessed portion includes a plurality of contact terminals arranged corresponding to a plurality of pins of the integrated circuit to be tested. When the detection board is changed, the frame or the IC coupling seat can be replaced with a desired one without the need of replacing the whole IC detection seat.

### BACKGROUND OF THE INVENTION

1. Field of the Invention

The present invention relates to a detection seat for a detection device. More particularly, the present invention relates to a detection seat for an IC detection device.

2. Description of the Related Art

A typical integrated circuit (IC) comprises a plurality of outwardly extending pins (in such as a ball grid array) for electrical connection with a printed circuit board (PCB), a printed wiring board (PCB), or an IC socket. To avoid poor electrical connection of the pins after assembly, each IC is tested after manufacture.

FIG. 1 of the drawings illustrates a conventional IC detection device for detecting each pin of an IC 2. The IC detection device comprises a detection board 3 and a detection seat 1 fixed on the detection board 3. The detection board 3 is designed according to the type of the circuit board provided by manufacturers or to the type of the circuit board of the product to be tested. However, various circuit boards from various manufacturers or of various products require various detection boards 3 due to different screwing positions. Namely, the detection seat 1 could not be assembled on the new detection board 3 for a different circuit board. Hence, a new mold for a new detection seat 1 is required, leading to an increase in the cost.

Further, there are various circuit boards 2 of different arrangements and sizes in the pins such that a specific detection seat 1 is required for a certain pin arrangement or pin size. Various detection seats 1 are thus required. The overall cost is thus high, for the detection seat 1 could not be dismantled.

### SUMMARY OF THE INVENTION

A detection seat for an IC detection device in accordance with the present invention comprises a frame and an IC coupling seat. The frame is adapted to be mounted on a detection board of an integrated circuit detection device. The IC coupling seat comprises an outer perimeter releasably engaged with the frame. The IC coupling seat comprises a recessed portion adapted for receiving an integrated circuit to be tested. The recessed portion includes a plurality of contact terminals arranged corresponding to a plurality of pins of the integrated circuit to be tested.

When the detection board is changed, the frame or the IC coupling seat can be replaced with a desired one without the need of replacing the whole IC detection seat.

Preferably, the IC coupling seat comprises a bottom plate, a substrate on top of the bottom plate, and an upper plate on top of the substrate. The bottom plate, the substrate, and the upper plate comprise a plurality of aligned through-holes with different diameters to prevent the contact terminals from disengaging from the substrate. Each contact terminal includes an upper section extending out of the upper plate, a lower section extending out of the bottom plate, and a resilient conductive element between the upper section and the lower section.

Preferably, the frame comprises at least one through-hole and at least one engaging member for extending through the through-hole and adapted for engaging with at least one engaging member on the detection board.

Preferably, the engaging member of the frame is a fastener and wherein the engaging member of the detection board is a screw hole.

Other objectives, advantages, and novel features of the invention will become more apparent from the following detailed description when taken in conjunction with the accompanying drawings.

### BRIEF DESCRIPTION OF THE DRAWINGS

FIG. 1 is a perspective view, partly exploded, of a conventional IC detection device.

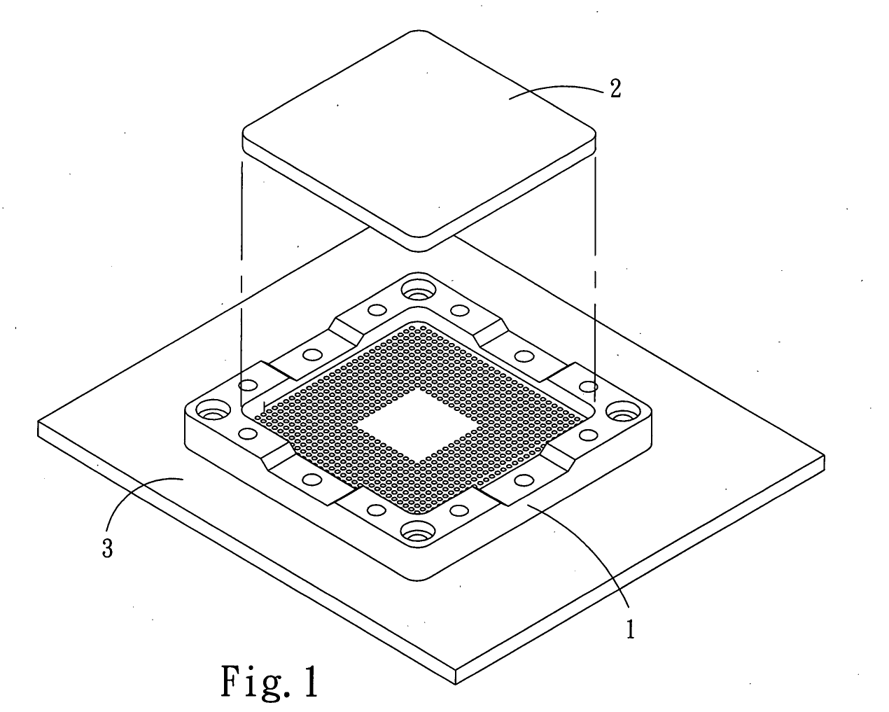

FIG. 2 is a perspective view, partly exploded, of an IC detection device with a detection seat in accordance with the present invention.

FIG. 3 is an exploded perspective view illustrating a frame and an IC coupling seat of the detection seat in accordance with the present invention.

FIG. 4 is a sectional view the IC detection device in FIG. 2.

FIG. 5 is a view similar to FIG. 4, illustrating a modified embodiment of the present invention.

### DETAILED DESCRIPTION OF THE INVENTION

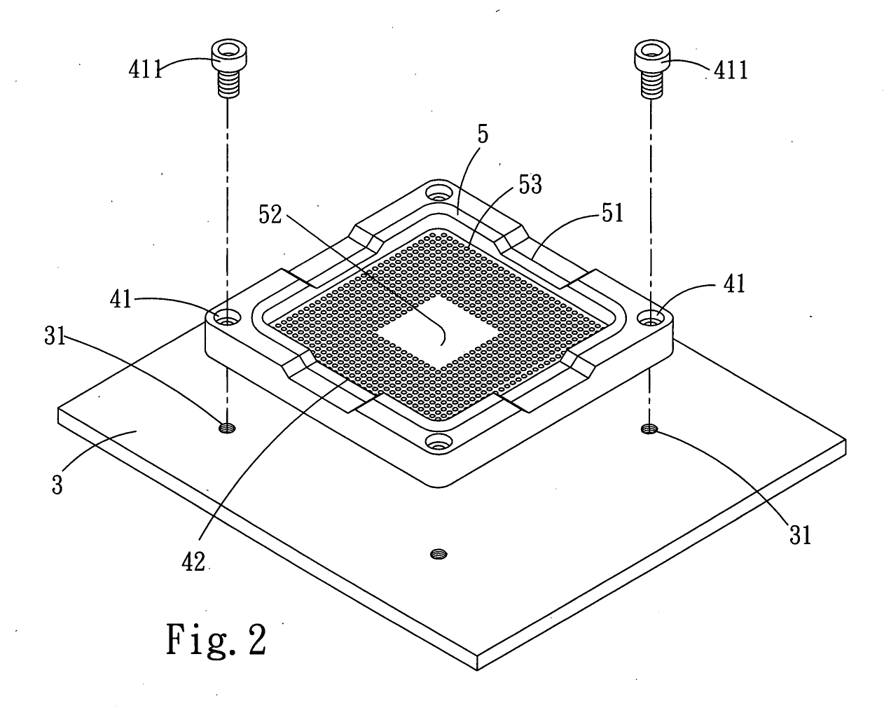

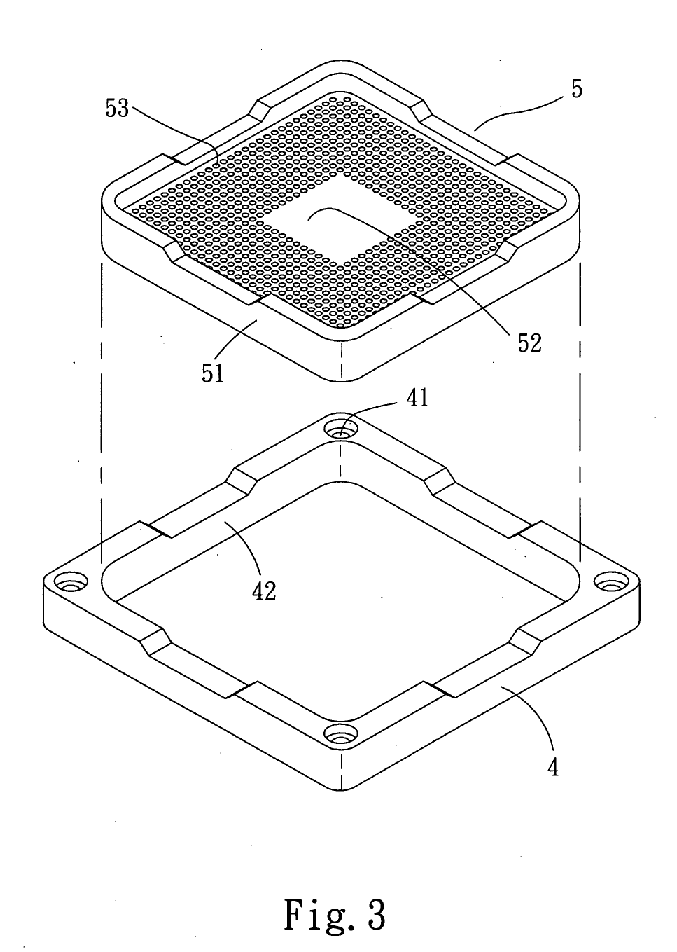

Referring to FIGS. 2 through 4, a detection seat in accordance with the present invention is coupled with a detection board 3 to form an IC detection device. The detection seat in accordance with the present invention comprises a frame 4 and an IC coupling seat 5. The frame 4 is removably mounted on the detection board 3. The detection board 3 includes at least one first engaging member 31 (four in this example). The frame 4 includes at least one through-hole 41 (four in this embodiment) aligned with the first engaging members 31. A second engaging member 411 is extended through each through-hole 41 and engaged with the associated first engaging member 31, thereby fixing the frame 4 on the detection board 3. The location of the second engaging members 411 may be adjusted according to the position of the first engaging members 31 of the detection board 3. By such an arrangement, when the detection board 3 is changed according to need, the frame 4 can be replaced with a desired one without the need of replacing the whole IC detection seat. The cost is cut, as the frame 4 is inexpensive.

In this example, the first engaging member 31 is a screw hole whereas the second engaging member 411 is a fastener for screwing the frame 4 to the detection board 3.

The IC coupling seat 5 includes an outer perimeter 51 for engaging with an inner perimeter 42 of the frame 4. The IC coupling seat 5 further includes a recessed portion 52 for receiving an IC 2 to be tested. The recessed portion 52 includes a plurality of contact terminals 53 arranged corresponding to the arrangement of the pins 21 of the IC 2. The IC coupling seat 5 can be easily mounted into or removed from the frame 4. The size of the frame 4 can be selected to correspond to that of the IC coupling seat 5. Thus, the detection seat in accordance with the present invention can be used with integrated circuits 2 of various sizes and/or various pin arrangements.

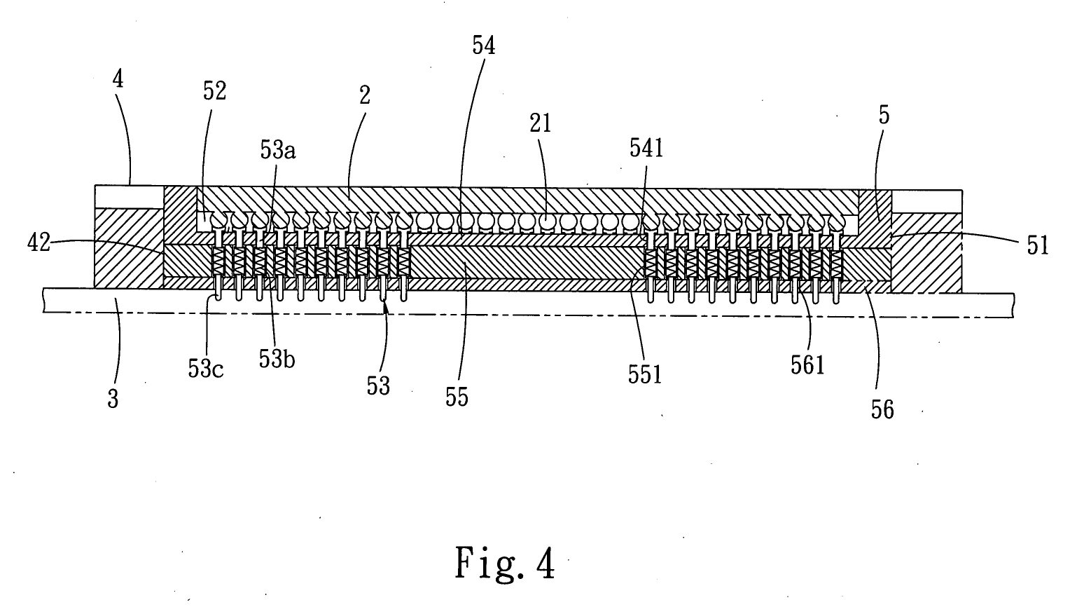

Still referring to FIG. 4, the IC coupling seat 5 includes an upper plate 54, a substrate 55, and a bottom plate 56 superimposed on each other in sequence. The upper plate 54, the substrate 55, and the bottom plate 56 include a plurality of aligned through-holes 541, 551, and 561 with different diameters to prevent the contact terminals 53 from disengaging from the substrate 55. In this embodiment, each contact terminal 53 includes an upper section 53a extending out of the upper plate 54 for electrical connection with an associated pin 21 of the IC 2 to be tested. Each contact terminal 53 further includes a lower section 53b extending out of the bottom plate 56 for electrical connection with an associated contact (not shown) on the detection board 3. A resilient conductive element 53c is mounted between the upper section 53a and the lower section 53b of each contact terminal 53. A reliable electrical connection is obtained by such an arrangement.

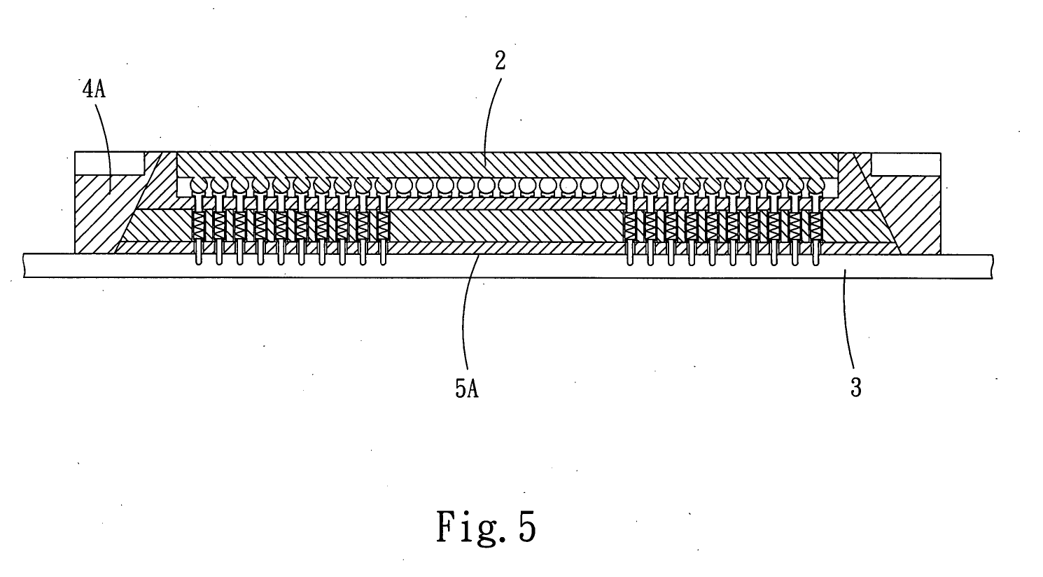

FIG. 5 illustrates a modified embodiment of the invention, wherein the frame 4A and the IC coupling seat 5A are in dovetail connection.

As apparent from the foregoing, when the detection board 3 is changed, the frame 4 or the IC coupling seat 5 can be replaced with a desired one without the need of replacing the whole IC detection seat.

Although specific embodiments have been illustrated and described, numerous modifications and variations are still possible without departing from the essence of the invention. The scope of the invention is limited by the accompanying claims.

What is claimed is:

1. A detection seat for an IC detection device, the detection seat comprising:
a frame adapted to be mounted on a detection board of an integrated circuit detection device; and
an integrated circuit (IC) coupling seat comprising an outer perimeter releasably engaged with the frame, the IC coupling seat comprising a recessed portion adapted for receiving an integrated circuit to be tested, the recessed portion including a plurality of contact terminals arranged corresponding to a plurality of pins of the integrated circuit to be tested.

2. The detection seat for an IC detection device as claimed in claim 1 wherein the IC coupling seat comprises a bottom plate, a substrate on top of the bottom plate, and an upper plate on top of the substrate, the bottom plate, the substrate, and the upper plate comprising a plurality of aligned through-holes with different diameters to prevent the contact terminals from disengaging from the substrate, each said contact terminal including an upper section extending out of the upper plate, a lower section extending out of the bottom plate, and a resilient conductive element between the upper section and the lower section.

3. The detection seat for an IC detection device as claimed in claim 1 wherein the frame comprises at least one through-hole and at least one engaging member for extending through said at least one through-hole and adapted for engaging with at least one engaging member on the detection board.

4. The detection seat for an IC detection device as claimed in claim 3 wherein said at least one engaging member of the frame is a fastener and wherein said at least one engaging member of the detection board is a screw hole.
